(19) United States
(12) Patent Application Publication
(10) Pub. No.: US 2022/0179329 A1
(43) Pub. Date: Jun. 9, 2022

(54) OPTICAL ELEMENT AND EUV LITHOGRAPHIC SYSTEM

(71) Applicant: Carl Zeiss SMT GmbH, Oberkochen (DE)

(72) Inventors: Anastasia Gonchar, Ulm (DE); Matthias Sturm, Waiblingen (DE); Christoph Nottbohm, Ulm (DE)

(21) Appl. No.: 17/681,876

(22) Filed: Feb. 28, 2022

Related U.S. Application Data
(63) Continuation of application No. PCT/EP2020/072119, filed on Aug. 6, 2020.

(30) Foreign Application Priority Data
Aug. 28, 2019 (DE) 10 2019 212 910.2

(51) Int. Cl. G03F 7/20; G02B 1/14; G02B 5/08; G21K 1/06

(52) U.S. Cl. CPC G03F 7/70958; G03F 7/70033; G21K 1/062; G02B 1/14; G02B 5/0816; G03F 7/70983

(57) ABSTRACT

An optical element (1) includes: a substrate (2); applied to the substrate (2), a multilayer system (3) which reflects EUV radiation (4); and also applied to the multilayer system (3), a protective layer system (5) which comprises a first layer (5a), a second layer (5b) and a third, in particular topmost layer (5c), where the first layer (5a) is disposed closer to the multilayer system (3) than the second layer (5b), and where the second layer (5b) is disposed closer to the multilayer system (3) than the third layer (5c). The second layer (5b) and the third layer (5c) and also preferably the first layer (5a) each have a thickness (d₂, d₃, d₁) of between 0.5 nm and 5.0 nm. A related EUV lithography system having at least one such optical element is also described.

### CROSS-REFERENCE TO RELATED APPLICATION

This is a Continuation of International Application PCT/EP2020/072119, which has an international filing date of Aug. 6, 2020, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2019 212 910.2 filed on Aug. 28, 2019.

### FIELD OF THE INVENTION

The invention relates to an optical element comprising: a substrate; applied to the substrate, a multilayer system which reflects EUV radiation; and also, applied to the multilayer system, a protective layer system which comprises a first layer, a second layer and a third, in particular topmost layer, where the first layer is disposed closer to the multilayer system than the second layer and where the second layer is disposed closer to the multilayer system than the third layer. The invention also relates to an EUV lithography system which comprises at least one such optical element.

### BACKGROUND

For the purposes of this application, an EUV lithography system is understood as meaning an optical system or an optical arrangement for EUV lithography, i.e. an optical system that can be used in the field of EUV lithography. Apart from an EUV lithography apparatus used for producing semiconductor components, the optical system can be for example an inspection system for the inspection of a photomask (hereinafter also referred to as a reticle) used in an EUV lithography apparatus, for the inspection of a semiconductor substrate to be structured (hereinafter also referred to as a wafer), or a metrology system used for measuring an EUV lithography apparatus or parts thereof, for example for measuring a projection system.

EUV radiation (extreme ultraviolet radiation) is understood to mean radiation in a wavelength range of between approximately 5 nm and approximately 30 nm, for example at 13.5 nm. Since EUV radiation is greatly absorbed by most known materials, the EUV radiation is typically guided through the EUV lithography system with the aid of reflective optical elements.

The laminae or layers of a reflective multilayer system in the form of a coating on a reflective optical element (EUV mirror) are subject to harsh conditions in operation in an EUV lithography system, in particular in an EUV lithography apparatus: For example, EUV radiation having a high radiant power impinges on the layers. The EUV radiation also has the effect that some of the EUV mirrors heat up to high temperatures of possibly several 100° C. The residual gases in a vacuum environment in which the EUV mirrors are generally operated (e.g. oxygen, nitrogen, hydrogen, water, and further residual gases present in an ultra-high vacuum, such as noble gases, for example) may also impair the layers of the reflective multilayer system in the form of the coating, particularly if said gases are converted into reactive species such as ions or radicals, for example into a hydrogen-containing plasma, by the effect of the EUV radiation. The ventilation of the vacuum environment in a pause in operation, and unwanted leaks that occur, can also lead to damage to the layers of the reflective multilayer system. In addition, the layers of the reflective multilayer system may be contaminated or damaged by hydrocarbons arising during operation, by volatile hydrides, by drops of tin or tin ions, by cleaning media, etc.

In order to protect the layers of the reflective multilayer system of the optical element, a protective layer system is employed which is applied to the multilayer system and which may itself comprise one or more layers. The layers of the protective layer system may fulfill various functions in order to prevent typical damage scenarios; for example, the formation of bubbles or the detachment of layers (delamination), especially as a result of reactive hydrogen which is present in the residual gas atmosphere and/or is used for cleaning. Especially in the case of optical elements which are in the vicinity of an EUV radiation source, in which tin droplets are bombarded with a laser beam in order to generate EUV radiation, a contaminating layer of Sn may be formed and/or the layers of the multilayer system may mix with Sn.

WO 2014/139694 A1 describes an optical element wherein the protective layer system comprises at least one first and one second layer, where the first layer is disposed closer to the multilayer system than the second layer. The first layer may have a lower solubility for hydrogen than the second layer. The protective layer system may comprise a third, topmost layer, formed of a material having a high recombination rate for hydrogen. The first layer, the second layer and/or the third layer may be formed of a metal or metal oxide. The material of the third, topmost layer may be selected from the group comprising: Mo, Ru, Cu, Ni, Fe, Pd, V, Nb and their oxides.

An optical element configured as described above has also been disclosed by WO 2013/124224 A1. The optical element comprises a protective layer system having a topmost layer and also having at least one further layer under the topmost layer, the thickness of which is greater than the thickness of the topmost layer. The material of the topmost layer is selected from chemical compounds comprising: Oxides, carbides, nitrides, silicates and borides.

EP 1 065 568 B1 describes a lithographic projection device which comprises a reflector having a multilayer reflective coating and having a capping layer. The capping layer may have a thickness of between 0.5 nm and 10 nm. The capping layer may comprise two or three layers of different materials. The topmost layer may consist of Ru or Rh, the second layer of B₄C, BN, diamond-like carbon, Si₃N₄ or SiC. The material of the third layer matches the material of a layer of the multilayer reflective coating, and for example may be Mo.

A reflective optical element having a protective layer system which comprises two layers has been disclosed by EP 1 402 542 B 1. The protective layer system described therein has a topmost layer made of a material which resists oxidation and corrosion, e.g. Ru, Zr, Rh, Pd. The second layer serves as a barrier layer which consists of B₄C or Mo and which is intended to prevent the material of the topmost layer of the protective layer system from diffusing into the topmost layer of the multilayer system which reflects EUV radiation.

EP 1 364 231 B1 and U.S. Pat. No. 6,664,554 B2 disclose providing a self-cleaning optical element in an EUV lithography system, said optical element having a catalytic capping layer composed of Ru or Rh, Pd, Ir, Pt, Au for protecting a reflective coating against oxidation. A metallic layer composed of Cr, Mo or Ti may have been introduced between the capping layer and the surface of the mirror.

EP 1 522 895 B1 has disclosed a method and an apparatus in which at least one mirror is provided with a dynamic protective layer in order to protect the mirror against etching by ions. The method comprises feeding a gaseous substance (as and when necessary) into a chamber containing the at least one mirror. The gas is typically a gaseous hydrocarbon (C_{X}H_{Y}). The protective effect of the carbon layer deposited in this way is limited, however, and the feeding and also the monitoring of the mirror necessitate a high outlay.

Other protective layer systems which are or may be formed of a plurality of layers are described in JP2006080478 A and also in JP4352977 B2.

### SUMMARY

It is an object of the invention to provide an optical element and an EUV lithography system wherein damage to the reflective multilayer system is prevented or at least retarded, allowing the lifetime of the optical element to be extended.

According to one formulation, this object is achieved with an optical element of the aforementioned kind wherein the second layer and the third layer and also preferably the first layer each have a thickness of between 0.5 nm and 5 nm.

The inventors have recognized that if the materials of the individual layers are selected appropriately, and even with a comparatively low thickness of the individual layers if the protective layer system is designed appropriately, it is possible to ensure a sufficient protective effect and hence a long lifetime of the optical element. The comparatively low thickness of the layers of the laminar layer system leads in general to a reduction in the absorption of the EUV radiation passing through the protective layer system, thereby increasing the reflectivity of the reflective optical element. It will be appreciated that the materials selected for the layers of the protective layer system ought to be materials which do not have too great an absorption for EUV radiation.

The protective layer system preferably has a (total) thickness of less than 10 nm, in particular of less than 7 nm. As has been described earlier on above, the reflectivity of the optical element can be increased with a comparatively thin protective layer system. Given a suitable selection of the materials and of the layer thicknesses for the protective layer system, it is possible, in spite of the low thickness of the protective layer system, to achieve sufficient protection and a long lifetime of the optical element.

In a further embodiment, the first layer, the second layer and/or the third layer are/is formed of a (metal) oxide or of a (metallic) mixed oxide. The oxide or mixed oxide may be a stoichiometric oxide or mixed oxide or may be a nonstoichiometric oxide or mixed oxide. Mixed oxides are composed of a plurality of oxides, meaning that their crystal lattice is made up of oxygen ions and the cations of a plurality of chemical elements. It has proven advantageous to use oxides in the layers of the multilayer system since they have high absorption for deep ultraviolet (DUV) radiation, which is generally generated by the EUV radiation source in addition to the EUV radiation and the propagation of which, through the EUV lithographic system, is undesirable.

It is advantageous for the oxides and/or mixed oxides to be applied in as defect-free a manner as possible, since the properties of oxides, such as their reducibility, for example, are critically dependent on the microstructure and on the presence of defects. In this regard, reference may be made, illustratively, to the article “Turning a Non-Reducible into a Reducible Oxide via Nanostructuring: Opposite Behaviour of Bulk ZrO₂ and ZrO₂ Nanoparticles towards H₂ Adsorption”, A.R. Puigdollers et al., Journal of Physical Chemistry C 120(28), 2016, to the article “Transformation of the Crystalline Structure of an ALD TiO₂ Film on a Ru Electrode by O₃ Pretreatment”, S. K. Kim et al., Electrochem. Solid-State Lett. 2006, 9(1), F5, to the article “Role of Metal/Oxide Interfaces in Enhancing the Local Oxide Reducibility”, P. Schlexer et al., Topics in Catalysis, October 2018, and also the article “Increasing Oxide Reducibility: The Role of Metal/Oxide Interfaces in the Formation of Oxygen Vacancies”, A. R. Puigdollers et al., ACS Catal. 2017, 7, 10, 6493-6513. For the application of oxides and/or mixed oxides in as defect-free a manner as possible, there must be a suitable selection made of the coating process, of the substrate material to which the respective layer is applied, and there must also be a suitable thickness stipulated for the respective layer applied.

In one development, the (stoichiometric or nonstoichiometric) oxide or the (stoichiometric or nonstoichiometric) mixed oxide of the third layer comprises at least one chemical element selected from the group comprising: Zr, Ti, Nb, Y, Hf, Ce, La, Ta, Al, Er, W, Cr.

In order to prevent degradation of the layers in the multilayer system and/or to counteract a reduction in the reflectivity, the material of the third layer ought to be stable with respect to cleaning media (aqueous, acidic, basic, organic solvents and surfactants), and also to reactive hydrogen (H⁺), i.e. hydrogen ions and/or hydrogen radicals, which are used in the cleaning of the surface of the protective layer system or of the third layer. Where the optical element is arranged in the vicinity of the EUV radiation source, the material of the third layer ought to be resistant to Sn and/or not to mix with Sn. In particular, Sn contaminations deposited on the third layer ought to be able to be removed from the surface of the third layer using reactive hydrogen (H⁺). The material of the third layer ought also to be resistant to redox reactions, in other words neither to be oxidized nor to be reduced —on contact with hydrogen, for example. The third layer also ought not to contain any substances which are volatile in an atmosphere containing oxygen and/or hydrogen. The oxides and mixed oxides of the metals described earlier on above meet these conditions or the great majority of these conditions.

In one development, the (stoichiometric or nonstoichiometric) oxide or the (stoichiometric or nonstoichiometric) mixed oxide of the second layer comprises at least one chemical element selected from the group comprising: Al, Zr, Y, La.

The material of the second layer ought fundamentally to be resistant to reactive hydrogen (H⁺) and also to Sn. The material of the second layer ought additionally to be redox-resistant. Where the material of the second layer is an oxide or a mixed oxide, it ought in particular to be inert to reduction by hydrogen and also blister-resistant. The material of the second layer ought also to be an H/O blocker, i.e., a material which, to as complete an extent as possible, prevents the passage of oxygen and also, preferably, of hydrogen into the underlying layers. The material of the second layer ought also to form an appropriate base for the growth of the third layer. The second layer also ought not to contain any substances which are volatile in an atmosphere containing oxygen and/or hydrogen. Besides oxides and mixed oxides, these conditions are met in particular by certain metallic materials (see below).

In another development, the (stoichiometric or nonstoichiometric) oxide or the (stoichiometric or nonstoichiometric) mixed oxide of the first layer comprises at least one chemical element selected from the group comprising: Al, Zr, Y. The material of the third layer ought also to be an H/O blocker, i.e., a material which, to as complete an extent as possible, prevents the passage of oxygen and also, preferably, of hydrogen into the underlying layers. The material of the first layer ought also fundamentally to be resistant to reactive hydrogen (H⁺) and also to the formation of blisters. The first layer ought also to form a barrier in order to protect the last layer of the multilayer system against mixing with the material of the second layer. Moreover, the material of the first layer ought to form an appropriate base for the growth of the second layer.

In another embodiment, the first layer and/or the second layer are/is formed of at least one metal (or of a mixture of metals, or of an alloy). In contrast to the third layer, which is formed preferably of an oxide or of a mixed oxide, the first layer and the second layer may be formed of (at least) one metal. The requirements with regard to resistance to cleaning media are less stringent for the first and second layers than for the third layer.

In one development, the second layer comprises or consists of a metal selected from the group comprising: Al, Zr, Y, Sc, Ti, V, Nb, La and also noble metals, in particular Ru, Pd, Pt, Rh, Ir, and mixtures thereof. Ru, Pd, Pt, Rh, Ir are noble metals, and more specifically are platinum metals.

In another embodiment, the first layer comprises or consists of a metal selected from the group comprising: Al, Mo, Ta, Cr and mixtures thereof. These materials are likewise good at meeting the requirements described earlier on above for the material of the first layer.

In another embodiment the material of the first layer is selected from the group comprising: C, B₄C, BN. With regard in particular to their properties as diffusion barrier layers, these materials have proven advantageous for preventing the material of the second layer in the protective layer system from diffusing into the topmost layer of the multilayer system.

The selection of suitable materials for the three layers and also any further layers (see below) requires harmonization in relation to their properties; in particular, the lattice constants, the coefficient of thermal expansion (CTE) and the free surface energies of the materials of the three layers ought to be harmonized with one another. Not every combination of the materials described earlier on above, therefore, is equally suitable for producing the protective layer system.

The layers of the protective layer system and also the layers of the reflective multilayer system may be applied in particular by a PVD (physical vapor deposition) coating process or by a CVD (chemical vapor deposition) coating process. The PVD coating process may, for example, comprise electron beam vapor deposition, magnetron sputtering, or laser beam vapor deposition (“pulsed laser deposition”, PLD). The CVD coating process may be, for example, a plasma-enhanced CVD process (PE-CVD) or an atomic layer deposition (ALD) process. Atomic layer deposition, in particular, enables very thin layers to be deposited.

In another embodiment, metallic layers and/or ions are implanted into the first layer, into the second layer and/or into the third layer, and/or preferably metallic particles are deposited on the first layer, on the second layer and/or on the third layer, said particles and ions being selected in particular from the group comprising: Pd, Pt, Rh, Ir. Particularly for the purpose of preventing the implantation of Sn ions, it may be advantageous if comparatively small amounts of ions are implanted into the first layer, into the second layer and/or into the third layer. The ions in question may be metal ions, preferably noble metal ions, in particular platinum metal ions—for example, Pd, Pt, Rh and also, optionally, Ir. Alternatively or additionally, the ions implanted into the respective layer may be noble gas ions, e.g., Ar ions, Kr ions or Xe ions.

Alternatively or additionally to the implantation of ions, the first, second and/or third layers may have been doped with metallic particles, preferably with noble metal particles, in particular with platinum metal particles. The metallic particles, preferably in the form of noble metal particles, in particular in the form of platinum metal particles, may also have been deposited on the surface of the respective layer(s), in particular on the surface of the third, topmost layer. As described in DE 10 2015 207 140 A1, which in its entirety, and by this reference, is incorporated and made part of the content of the present application, the application of (nano)particles to the respective layer enables the blocking of surface defects, with the consequence that at the positions in question, there can no longer be any adsorptions and/or dissociation processes and associated contaminant depositions. Particles are preferably applied/deposited only in individualized form, in particular in the form of individual atoms, or in clusters (e.g., in groups of not more than 25 atoms).

In another embodiment, the protective layer system comprises at least one further layer, in particular a sub-monolayer layer, which has a thickness of 0.5 nm or less and which comprises at least one metal, preferably at least one noble metal, in particular at least one platinum metal, which is preferably selected from the group comprising: Pd, Pt, Rh, Ir. The protective layer system may comprise the (thin) layer in order to reinforce the blockage effect of the three other layers with respect to hydrogen and/or oxygen. The (thin) further layer may in particular be a sub-monolayer layer, i.e., a layer which does not completely cover the underlying layer with a layer of atoms. The protective layer system may also comprise more than four layers, such as five, six or more layers, for example. The layers may be, for example, (thin) layers which counteract the mixing of adjacent layers by taking on the function of a diffusion barrier.

The multilayer system typically comprises alternately applied layers of a material having a comparatively higher real part of the refractive index at the operating wavelength (also called “spacer”) and of a material having a comparatively lower real part of the refractive index at the operating wavelength (also called “absorber”). As a result of this construction of the multilayer system, there is simulation, in a certain way, of a crystal whose lattice planes correspond to the absorber layers at which Bragg reflection takes place. The thicknesses of the spacer layers and of the absorber layers are determined as a function of the operating wavelength.

In another embodiment, the multilayer system comprises a topmost layer having a thickness of more than 0.5 nm. The topmost layer in this case is typically a spacer layer. In the event that the operating wavelength is situated at approximately 13.5 nm, the material of the spacer layers is typically silicon and the material of the absorber layers is molybdenum.

In another embodiment, the optical element takes the form of a collector mirror. In EUV lithography, collector mirrors are typically used as the first mirror after the EUV radiation source, downstream of a plasma radiation source, for example, in order to collect the radiation emitted in different directions by the radiation source and to reflect it in a bundled form to the next mirror. Owing to the high radiative intensity in the environment of the radiation source, molecular hydrogen that is present there with particularly high probability in the residual gas atmosphere can be converted into reactive (atomic and/or ionic) hydrogen with high kinetic energy, such that collector mirrors specifically are at particular risk, owing to penetration by reactive hydrogen, of exhibiting delamination phenomena at the layers of the protective layer system and/or at the upper layers of their multilayer system.

A further aspect of the invention relates to an EUV lithography system comprising: at least one optical element as described earlier on above. The EUV lithography system can be an EUV lithography apparatus for exposing a wafer, or can be some other optical arrangement that uses EUV radiation, for example an EUV inspection system, for example for inspecting masks, wafers or the like that are used in EUV lithography.

Further features and advantages of the invention are evident from the following description of exemplary embodiments of the invention, with reference to the figures of the drawing showing details associated with the invention, and from the claims. The individual features can each be realized individually by themselves or as a plurality in any desired combination in one variant of the invention.

### BRIEF DESCRIPTION OF THE DRAWINGS

Exemplary embodiments are illustrated in the schematic drawing and are explained in the following description. In the figures:

FIG. 1A shows a schematic illustration of an optical element in the form of an EUV mirror, which comprises a reflective multilayer system and also a protective layer system having three layers;

FIG. 1B shows a schematic illustration of the optical element of FIG. 1A, wherein ions and also metallic (nano)particles are implanted into the second layer of the protective layer system and deposited on the top side of the third layer,

FIG. 1C shows a schematic illustration of the optical element of FIGS. 1A and 1B, wherein the protective layer system comprises a fourth layer, composed of a noble metal; and

FIG. 2 shows a schematic illustration of an EUV lithography apparatus.

### DETAILED DESCRIPTION

In the following description of the drawings, identical reference signs are used for identical or functionally identical components.

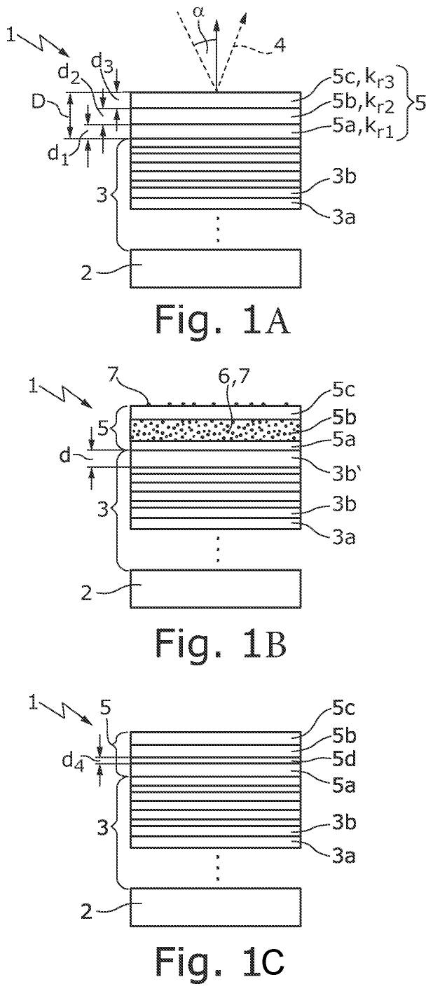

FIGS. 1A-C schematically show the construction of an optical element 1 which comprises a substrate 2 consisting of a material having a low coefficient of thermal expansion, e.g., of Zerodur®, ULE® or Clearceram®. The optical element 1 shown in FIGS. 1A-C is configured for reflecting EUV radiation 4 which is incident on the optical element 1 with normal incidence, i.e. at angles of incidence a of typically less than approximately 45° with respect to the surface normal. For the reflection of EUV radiation 4, a reflective multilayer system 3 is applied to the substrate 2. The multilayer system 3 comprises alternately applied layers of a material having a comparatively higher real part of the refractive index at the operating wavelength (also called “spacer” 3b) and of a material having a comparatively lower real part of the refractive index at the operating wavelength (also called “absorber” 3a), where an absorber-spacer pair forms a stack. As a result of this construction of the multilayer system 3, a crystal is simulated, in a certain way, with lattice planes corresponding to the absorber layers at which Bragg reflection takes place. In order to ensure sufficient reflectivity, the multilayer system 3 comprises a number of generally more than fifty alternating layers 3a, 3b.

The thicknesses of the individual layers 3a, 3b and also of the repeating stacks can be constant over the entire multilayer system 3 or else vary, depending on what spectral or angle-dependent reflection profile is intended to be achieved. The reflection profile can also be influenced in a targeted manner by the basic structure composed of absorber 3a and spacer 3b being supplemented by additional more and less absorbing materials in order to increase the possible maximum reflectivity at the respective operating wavelength. To that end, in some stacks, absorber and/or spacer materials can be mutually interchanged, or the stacks can be constructed from more than one absorber and/or spacer material. The absorber and spacer materials can have constant or varying thicknesses over all the stacks in order to optimize the reflectivity. Furthermore, it is also possible to provide additional layers for example as diffusion barriers between spacer and absorber layers 3a, 3b.

In the present example, wherein the optical element 1 has been optimized for an operating wavelength of 13.5 nm, in other words for an optical element 1 which exhibits maximum reflectivity at a wavelength of 13.5 nm under substantially normal incidence of EUV radiation 4, the stacks of the multilayer system 3 comprise alternating silicon layers 3a and molybdenum layers 3b. In this system, the silicon layers 3b correspond to the layers having a relatively higher real part of the refractive index at 13.5 nm and molybdenum layers 3a correspond to layers having a comparatively lower real part of the refractive index at 13.5 nm. Depending on the exact value of the operating wavelength, other material combinations, such as e.g. molybdenum and beryllium, ruthenium and beryllium, or lanthanum and B₄C, are likewise possible.

In order to protect the multilayer system 3 from degradation, a protective layer system 5 is applied to the multilayer system 3. In the example shown in FIG. 1A, the protective layer system consists of a first layer 5a, a second layer 5b and a third layer 5c. In this arrangement, the first layer 5a is disposed closer to the multilayer system 3 than the second layer 5b. The second layer 5b is disposed closer to the multilayer system 3 than the third layer 5c, which forms the topmost layer of the protective layer system 5, on whose exposed surface the interface with the surrounding environment is formed.

The first layer 5a has a first thickness d₁, the second layer 5b has a second thickness d₂, and the third layer 5c has a third thickness d₃, each of these thicknesses being situated in a range between 0.5 nm and 5.0 nm. The protective layer system 5 has a total thickness D (here: D=d₁+d₂+d₃) which is less than 10 nm, optionally less than 7 nm.

In the example shown, the material of the third, topmost layer 5c is a (stoichiometric or nonstoichiometric) oxide or a (stoichiometric or nonstoichiometric) mixed oxide which comprises at least one chemical element selected from the group comprising: Zr, Ti, Nb, Y, Hf, Ce, La, Ta, Al, Er, W, Cr.

The material of the second layer 5b may likewise be a (stoichiometric or nonstoichiometric) oxide and/or a (stoichiometric or nonstoichiometric) mixed oxide which is selected from the group comprising: Al, Zr, Y, La. Alternatively to an oxide or mixed oxide, the material of the second layer 5b may comprise (at least) one metal. The metal may be selected, for example, from the group comprising: Al, Zr, Y, Sc, Ti, V, Nb, La and noble metals, preferably platinum metals, in particular Ru, Pd, Pt, Rh, Ir.

The material of the first layer 5a may likewise be a (stoichiometric or nonstoichiometric) oxide or a (stoichiometric or nonstoichiometric) mixed oxide. The oxide or the mixed oxide typically comprises at least one optical element selected from the group comprising: Al, Zr, Y. Alternatively the first layer 5a may comprise or consist of (at least) one metal. The metal may in particular be selected from the group comprising: Al, Mo, Ta, Cr. The material of the first layer 5a may alternatively be selected from the group comprising: C, B₄C, BN. These materials have been found to be advantageous as diffusion barriers.

The protective effect of the protective layer system 5 is dependent not only on the materials which are selected for the three layers 5a-5c but also on whether the materials are a good fit in terms of their properties—for example, with regard to their lattice constants, their coefficients of thermal expansion, their free surface energies, etc.

Described below are two examples of a protective layer system 3, in which the materials have been harmonized with one another in terms of their properties. In the first example, the third layer 5c is formed of TiOₓ and has a thickness d₃ of 1.5 nm, the second layer 5b is formed of Ru and has a thickness d₂ of 2 nm, and the first layer 5a is formed of AlOₓ and likewise has a thickness d₁ of 2 nm. In the second example, the third layer 5c is formed of YOₓ and has a thickness d₃ of 2 nm, the second layer 5b is formed of Rh and has a thickness d₂ of 1.5 nm, and the first layer 5a is formed of Mo and has a thickness d₁ of 3 nm. The total layer thickness D of the protective layer system 5 is 5.5 nm in the first example and 6.5 nm in the second example. It will be appreciated that as well as the examples described here, other combinations of materials are also possible, and that the thicknesses of the three layers 5a-c of the protective layer system 5 may differ from the values indicated above.

FIG. 1B shows an optical element 1 wherein small amounts of ions 6 have been implanted into the second layer 5b in order to counteract the implantation of Sn ions possibly present in the environment of the optical element 1. The ions 6 may be, for example, noble gas ions, e.g., Ar ions, Kr ions or Xe ions. The implanted ions may also be noble metal ions, as for example Pd ions, Pt ions, Rd ions, or possibly Ir ions. The noble metal ions serve as hydrogen and/or oxygen blockers.

Additionally or alternatively to the implantation of ions, it is also possible for metallic particles to be implanted into the second layer 5b, by, for example, doping the second layer 5b with metallic (nano)particles 7, in particular with particles and/or with (foreign) atoms of a noble metal, e.g., of Pd, Pt, Rh, Ir. It will be appreciated that the implantation of ions 6 and of metallic particles 7 may also take place for the first layer 5a and for the third layer 5c.

In the example shown in FIG. 1B, metallic (nano)particles 7, more specifically noble metal particles and/or noble metal atoms, have been applied to the third, topmost layer 5c. The application of (nano)particles 7, in particular in the form of Pd, Pt, Rh, Ir, may take place in individualized form, in particular in the form of individual atoms, or else in clusters (e.g. in groups of not more than 25 atoms).

In the example shown in FIG. 1B, the multilayer system 3 of the optical element 1 comprises a topmost layer 3b′ of silicon with a thickness d of more than 0.5 nm. The thickness d of the topmost layer 3b′ is selected such that the reflection of the multilayer system 3 is at its maximum. It will be appreciated that, alternatively, the topmost layer 3b′ of the multilayer system 3 may be embodied as in FIG. 1A, i.e. may have a thickness of less than 0.5 nm.

FIG. 1C shows a protective layer system 3 which between the first layer 5a and the second layer 5b comprises a further, fourth layer 5d, which has a thickness d₄ of not more than 0.5 nm. The fourth layer 5d comprises a metal, more specifically a noble metal, for example Pd, Pt, Rh and/or Ir. The fourth (thin) layer 5d forms a sub-monolayer layer and contributes to the minimization of defects, hence being able to serve as a barrier to the penetration of hydrogen and/or oxygen into the underlying first layer 5a. It will be appreciated that the fourth layer 5d for the purpose of minimizing defects may also be formed between the second layer 5b and the third layer 5c or optionally on the third layer 5c, which in that case does not form the topmost layer of the protective layer system 5. The protective layer system 5 may also optionally comprise a fifth, sixth, . . . layer, in order to minimize the number of defects and/or in order to form a barrier for hydrogen and/or for oxygen.

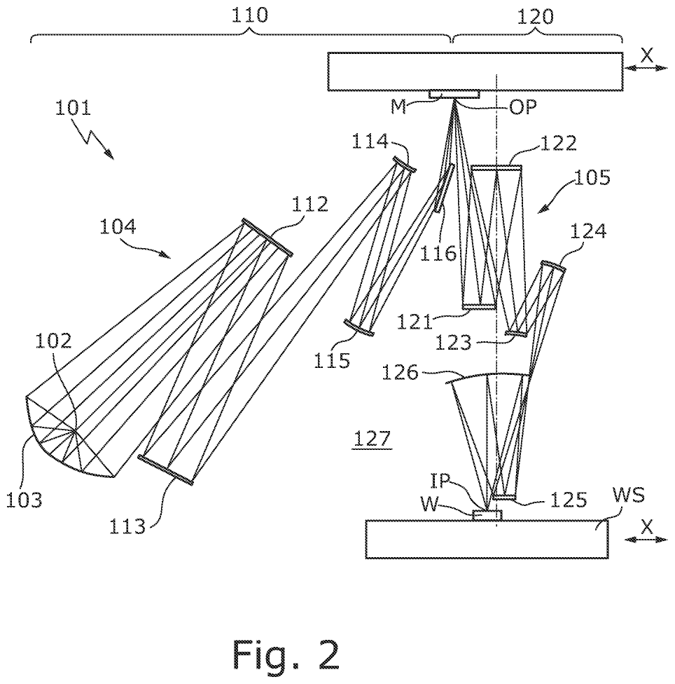

The optical elements 1 illustrated in FIGS. 1A-C can be used in an EUV lithography system in the form of an EUV lithography apparatus 101, as is illustrated schematically below in the form of a so-called wafer scanner in FIG. 2.

The EUV lithography apparatus 101 comprises an EUV light source 102 for generating EUV radiation, which has a high energy density in the EUV wavelength range below 50 nanometers, in particular between approximately 5 nanometers and approximately 15 nanometers. The EUV light source 102 can be embodied, for example, in the form of a plasma light source for generating a laser-induced plasma. The EUV lithography apparatus 101 shown in FIG. 2 is designed for an operating wavelength of the EUV radiation of 13.5 nm, for which the optical elements 1 illustrated in FIGS. 1A-C are also designed. However, it is also possible for the EUV lithography apparatus 101 to be configured for a different operating wavelength in the EUV wavelength range, such as 6.8 nm, for example.

The EUV lithography apparatus 101 further comprises a collector mirror 103 in order to focus the EUV radiation of the EUV light source 102 to form a bundled illumination beam 104 and to increase the energy density further in this way. The illumination beam 104 is arranged to illuminate a structured object M with an illumination system 110, which in the present example has five reflective optical elements 112 to 116 (mirrors).

The structured object M can be for example a reflective photomask, which has reflective and non-reflective, or at least less reflective, regions for producing at least one structure on the object M. Alternatively, the structured object M can be a plurality of micro-mirrors, which are arranged in a one-dimensional or multi-dimensional arrangement and which are optionally movable about at least one axis, in order to set the angle of incidence of the EUV radiation on the respective mirror.

The structured object M reflects part of the illumination beam 104 and shapes a projection beam path 105, which carries the information about the structure of the structured object M and is radiated into a projection lens 120, which generates a projected image of the structured object M or of a respective partial region thereof on a substrate W. The substrate W, for example a wafer, comprises a semiconductor material, for example silicon, and is disposed on a mounting, which is also referred to as a wafer stage WS.

In the present example, the projection lens 120 has six reflective optical elements 121 to 126 (mirrors) in order to generate an image of the structure that is present at the structured object M on the wafer W. The number of mirrors in a projection lens 120 typically lies between four and eight; however, only two mirrors can also be used, if appropriate.

The reflective optical elements 103, 112 to 116 of the illumination system 110 and the reflective optical elements 121 to 126 of the projection lens 120 are arranged in a vacuum environment 127 during the operation of the EUV lithography apparatus 101. A residual gas atmosphere containing, inter alia, oxygen, hydrogen and nitrogen is formed in the vacuum environment 127.

The optical element 1 illustrated in FIGS. 1A-C can be one of the optical elements 103, 112 to 115 of the illumination system 110 or one of the reflective optical elements 121 to 126 of the projection lens 120 which are designed for normal incidence of the EUV radiation 4. In particular, the optical element 1 of FIGS. 1A-C may be the collector mirror 103, which in the operation of the EUV lithography apparatus 101 is exposed not only to reactive hydrogen but also to Sn contaminations. The protective layer system 5 described in connection with FIGS. 1A-C enables the lifetime of the collector mirror 103 to be significantly extended, and in particular this mirror can be used again after cleaning, for example.

What is claimed is:

1. An optical element, comprising:
a substrate;
applied to the substrate, a multilayer system which reflects extreme ultraviolet (EUV) radiation; and
applied to the multilayer system, a protective layer system which comprises a first layer, a second layer and a third layer, where the first layer is disposed closer to the multilayer system than is the second layer, and where the second layer is disposed closer to the multilayer system than is the third layer,
wherein the second layer and the third layer both have a thickness of between 0.5 nm and 5.0 nm, wherein the first layer is formed of a stoichiometric or nonstoichiometric oxide or of a stoichiometric or nonstoichiometric mixed oxide, and
wherein the oxide or the mixed oxide of the first layer comprises at least one chemical element selected from the group consisting essentially of: Al, Zr, Y.

2. The optical element as claimed in claim 1, wherein the third layer is a topmost layer of the protective layer system, and wherein the first layer also has a thickness between 0.5 nm and 5.0 nm.

3. The optical element as claimed in claim 1, wherein the second layer and/or the third layer are/is formed of a stoichiometric or nonstoichiometric oxide or of a stoichiometric or nonstoichiometric mixed oxide.

4. The optical element as claimed in claim 3, wherein the oxide or mixed oxide of the third layer comprises at least one chemical element selected from the group consisting essentially of: Zr, Ti, Nb, Y, Hf, Ce, La, Ta, Al, Er, W, Cr.

5. The optical element as claimed in claim 3, wherein the oxide or mixed oxide of the second layer comprises at least one chemical element selected from the group consisting essentially of: Al, Zr, Y, La.

6. An optical element comprising:
a substrate;
applied to the substrate, a multilayer system which reflects EUV radiation; and
applied to the multilayer system, a protective layer system which comprises a first layer, a second layer and a third layer, where the first layer is disposed closer to the multilayer system than is the second layer, and where the second layer is disposed closer to the multilayer system than is the third layer,
wherein the second layer and the third layer both have a thickness of between 0.5 nm and 5.0 nm, and wherein the first layer comprises or consists of a metal selected from the group consisting essentially of: Al, Mo, Ta, Cr.

7. The optical element as claimed in claim 6, wherein the third layer is a topmost layer of the protective layer system, and wherein the first layer also has a thickness between 0.5 nm and 5.0 nm.

8. The optical element as claimed in claim 6, wherein the second layer is formed of at least one metal.

9. The optical element as claimed in claim 8, wherein the second layer comprises or consists of a metal selected from the group consisting essentially of: Al, Zr, Y, Sc, Ti, V, Nb, La and noble metals.

10. The optical element as claimed in claim 9, wherein the second layer comprises or consists of Ru, Pd, Pt, Rh, or Ir.

11. An optical element comprising:
a substrate;
applied to the substrate, a multilayer system which reflects EUV radiation; and
applied to the multilayer system, a protective layer system which comprises a first layer, a second layer and a third, topmost layer, where the first layer is disposed closer to the multilayer system than is the second layer, and where the second layer is disposed closer to the multilayer system than is the third layer,
wherein the first layer directly adjoins the second layer, and the second layer directly adjoins the third layer,
wherein the second layer and the third layer both have a thickness of between 0.5 nm and 5.0 nm, and wherein the material of the first layer is selected from the group consisting essentially of: C, B₄C, BN.

12. The optical element as claimed in claim 11, wherein the first layer also has a thickness between 0.5 nm and 5.0 nm.

13. The optical element as claimed in claim 1, wherein ions and/or metallic particles are implanted into the first layer, into the second layer and/or into the third layer, and/or wherein metallic particles are applied to the first layer, to the second layer and/or to the third layer.

14. The optical element as claimed in claim 13, wherein the metallic particles are selected from the group consisting of: Pd, Pt, Rh, Ir.

15. The optical element as claimed in claim 1, wherein the protective layer system comprises at least one further layer having a thickness of 0.5 nm or less and comprising at least one metal.

16. The optical element as claimed in claim 15, wherein the at least one further layer is a sub-monolayer layer and wherein the at least one metal is selected from the group consisting essentially of: Pd, Pt, Rh, Ir.

17. The optical element as claimed in claim 1, wherein the multilayer system comprises a topmost layer having a thickness of more than 0.5 nm.

18. The optical element as claimed in claim 1, wherein the protective layer system has a thickness of less than 10 nm.

19. The optical element as claimed in claim 1, which is configured as a collector mirror.

20. An EUV lithography system comprising: at least one optical element as claimed in claim 1.
